(19) United States
(12) Patent Application Publication
(10) Pub. No.: US 2013/0313003 A1
(43) Pub. Date: Nov. 28, 2013

(54) MULTILAYER WIRING BOARD

(71) Applicant: Waka Manufacturing CO., LTD., Tokyo (JP)

(72) Inventors: Hiroshi Okayama, Tokyo (JP); Toru Takada, Kanagawa (JP)

(73) Assignee: WAKA MANUFACTURING CO., LTD., Tokyo (JP)

(21) Appl. No.: 13/899,243

(22) Filed: May 21, 2013

(30) Foreign Application Priority Data
May 28, 2012 (JP) 2012-121419

(51) Int. Cl. H05K 1/02

(52) U.S. Cl. CPC H05K 1/0237
USPC 174/251

(57) ABSTRACT

A multilayer wiring board includes a first dielectric layer, a high-frequency signal line formed on a first surface of the first dielectric layer, a ground layer formed on a second surface of the first dielectric layer, and a second dielectric layer covering part of the ground layer. The high-frequency signal line is electrically connectable to a center conductor of a coaxial structure. The second dielectric layer is spaced from an edge of the first dielectric layer to which the coaxial structure is to be connected, so that a ground exposure portion of the ground layer is exposed on the edge of the first dielectric layer. The ground layer is electrically connectable directly to an outer conductor of the coaxial structure at the ground exposure portion.

This application claims priority from Japanese patent application No. 2012-121419, filed on May 28, 2012, of which the specification, drawings, and claims are incorporated herein by reference in its entirety.

### BACKGROUND

1. Field of the Invention

The present invention relates to a multilayer wiring board used for a high-frequency signal interface or the like, and more particularly to a multilayer wiring board to which a coaxial structure such as a connector is connected.

2. Description of the Related Art

In recent years, demands for reduction in device scale have increasingly grown in applications for various communication devices used in wireless or optical communication systems. Size reduction is also necessarily required for circuit boards for communication devices and high-frequency device modules. Therefore, the dimension of high-frequency connectors used as internal or external interfaces of communication devices is desired to be reduced. As one of connectors that meet such market demands, a small-sized connector such as a push-on SMP connector or a push-on SMPM connector has been put into practice. Furthermore, such a small-sized connector has heretofore been mounted directly on a circuit board. See, e.g., JP-A 2004-363593.

When a small-sized connector is mounted directly on a circuit board, a center conductor of the small-sized connector is brought into close contact with a high-frequency signal line of the circuit board. An outer conductor of the small-sized connector is brought into close contact with a ground electrode of the circuit board, which is formed on the same plane as the high-frequency signal line. When a ground layer is formed on a rear face of a circuit board as in the case of a microstrip line, a ground electrode formed on a front face of the circuit board is electrically connected to the ground layer formed on the rear face of the circuit board via through holes. In this manner, connection of high-frequency signals is established between the small-sized connector and the circuit board.

Meanwhile, what is called a multilayer wiring board is used in order to enhance the functionality of communication devices within a limited space. A multilayer wiring board is formed of a multilayered substrate, and a control signal line is also incorporated in the same substrate while the transmission characteristics of high-frequency signals are maintained. FIGS. 1A and 1B show a conventional example of a multilayer wiring board. As shown in FIGS. 1A and 1B, a multilayer wiring board 200 has a dielectric layer 500, a high-frequency signal line 400 formed on a surface of the dielectric layer 500 for transmitting high-frequency signals, and a ground layer 600. Additionally, the multilayer wiring board 200 has a control signal layer 900 for forming a control signal circuit that controls devices mounted on the multilayer wiring board 200. Thus, in view of size reduction and space saving of a communication device, it is important to effectively combine the multilayer wiring board 200 with a small-sized connector for a high-frequency device module.

In a high-frequency region, the characteristic impedance is likely to be discontinuous at a connection portion between a small-sized connector and a multilayer wiring board. Particularly, in a case where high-speed data signals over 10 Gb/s are transmitted, the signal band is so wide as to arise a serious problem of quality degradation of signal waveforms that is caused by discontinuous characteristic impedance. For example, in the conventional device illustrated in FIG. 5 of JP-A 2004-363593, the amount of signal reflection increases at a discontinuous point of the characteristic impedance, thus deteriorating the flatness of the transmission-frequency characteristics. As a result, the waveform quality of high-speed data signals is degraded.

Furthermore, in the case of the multilayer wiring board illustrated in FIGS. 1A and 1B, when a small-sized connector 100 is mounted onto the multilayer wiring board 200, a center conductor 300 of the small-sized connector 100 is connected to the high-frequency signal line 400 formed on the surface of the dielectric layer 500. Projecting portions 1000A of an outer conductor 1000 of the small-sized connector 100, which serves as a ground, are connected to ground electrodes 1200 formed on the surface of the dielectric layer 500. In order to exert a function of the high-frequency signal line 400, the ground electrodes 1200 on the dielectric layer 500, which also has the high-frequency signal line 400 formed thereon, are electrically connected to the ground layer 600 via a plurality of through holes 130.

However, each of those through holes 130 has a thickness corresponding to the thickness of the dielectric layer 500 and thus has a finite inductance. Therefore, provision of many through holes cannot sufficiently reduce a ground inductance at a connection portion between the coaxial structure (connector) and the circuit board. Accordingly, impedance discontinuity thus caused results in deterioration of frequency characteristics in transmission of high-frequency signals. Furthermore, for wide-band and high-frequency signals, such as high-speed data signals, variations in location and dimension of the through holes 130 being formed exert additional influences, make it difficult to obtain good frequency characteristics.

### SUMMARY

The present invention has been made in view of the above drawbacks. It is, therefore, an object of the present invention to provide a multilayer wiring board capable of ensuring good frequency characteristics at a connection portion between a coaxial structure such as a connector and the multilayer wiring board so as to solve a problem of an increased ground inductance at the connection portion.

In order to attain the above object, according to an aspect of the present invention, there is provided a multilayer wiring board to which a coaxial structure for transmitting an electric signal with a center conductor and an outer conductor is connected. The multilayer wiring board includes a first dielectric layer, a high-frequency signal line formed on a first surface of the first dielectric layer, a ground layer formed on a second surface of the first dielectric layer, and a second dielectric layer covering part of the ground layer. The high-frequency signal line is electrically connectable to the center conductor of the coaxial structure. The second dielectric layer is spaced from an edge of the first dielectric layer to which the coaxial structure is to be connected, so that a ground exposure portion of the ground layer is exposed on the edge of the first dielectric layer. The ground layer is electrically connectable directly to the outer conductor of the coaxial structure at the ground exposure portion.

In other words, the multilayer wiring board has a multilayer structure including a dielectric layer having a high-frequency line, a ground layer, and a control signal layer for forming a control signal circuit. A coaxial structure capable of transmitting an electric signal with a center conductor and an outer conductor is connected to the multilayer wiring board. A ground exposure portion of the ground layer is exposed at a connection portion at which the coaxial structure is connected to the multilayer wiring board. A connection structure is provided at the connection portion to connect the ground exposure portion of the ground layer directly to the outer conductor of the coaxial structure for electrical conduction between the ground exposure portion of the ground layer and the outer conductor of the coaxial structure.

The ground exposure portion of the ground layer may electrically be connected to the outer conductor of the coaxial structure by a solder material, silver paste, or a conductive adhesive material applied to the ground exposure portion. Alternatively, the ground exposure portion of the ground layer may electrically be connected to the outer conductor of the coaxial structure by a contact protrusion extending from the outer conductor of the coaxial structure. Furthermore, it is preferable to locate the ground exposure portion right below the center conductor of the coaxial structure when the coaxial structure is connected to the multilayer wiring board. Moreover, the multilayer wiring board may further include a control signal layer formed on a surface of the second dielectric layer for forming a control signal circuit.

The coaxial structure may be a connector to be mounted on the multilayer wiring board.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1A is a side view showing an example of a conventional multilayer wiring board with a small-sized connector;

FIG. 1B is a cross-sectional view taken along line A-A of FIG. 1A;

FIG. 2A is a plan view schematically showing a configuration of a multilayer wiring board with a small-sized connector according to a first embodiment of the present invention;

FIG. 2B is a cross-sectional view taken along line B-B of FIG. 2A;

FIG. 2C is a cross-sectional view taken along line C-C of FIG. 2B;

FIG. 3A is a plan view schematically showing a configuration of the multilayer wiring board according to the first embodiment of the present invention;

FIG. 3B is a cross-sectional view taken along line D-D of FIG. 3A;

FIG. 3C is a plan view showing that a connector is to be mounted onto the multilayer wiring board of FIG. 3A.

FIG. 4 is a diagram schematically showing a configuration of a multilayer wiring board with a small-sized connector according to a second embodiment of the present invention;

FIG. 5A is a graph showing results of measuring frequency characteristics of transmission and reflection of high-frequency signals for a multilayer wiring board according to the present invention, for the purposes of comparison.

FIG. 5B is a graph showing results of measuring frequency characteristics of transmission and reflection of high-frequency signals for a conventional multilayer wiring board, for the purposes of comparison.

FIG. 6A is a diagram schematically showing a configuration of a multilayer wiring board with a small-sized connector according to a third embodiment of the present invention; and

FIG. 6B is a cross-sectional view taken along line E-E of FIG. 6A.

### DETAILED DESCRIPTION OF THE PREFERRED EMBODIMENTS

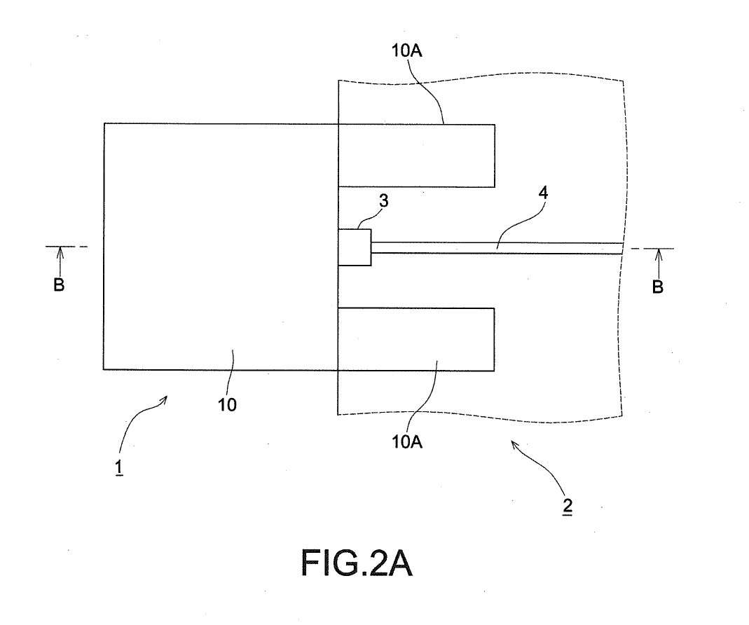

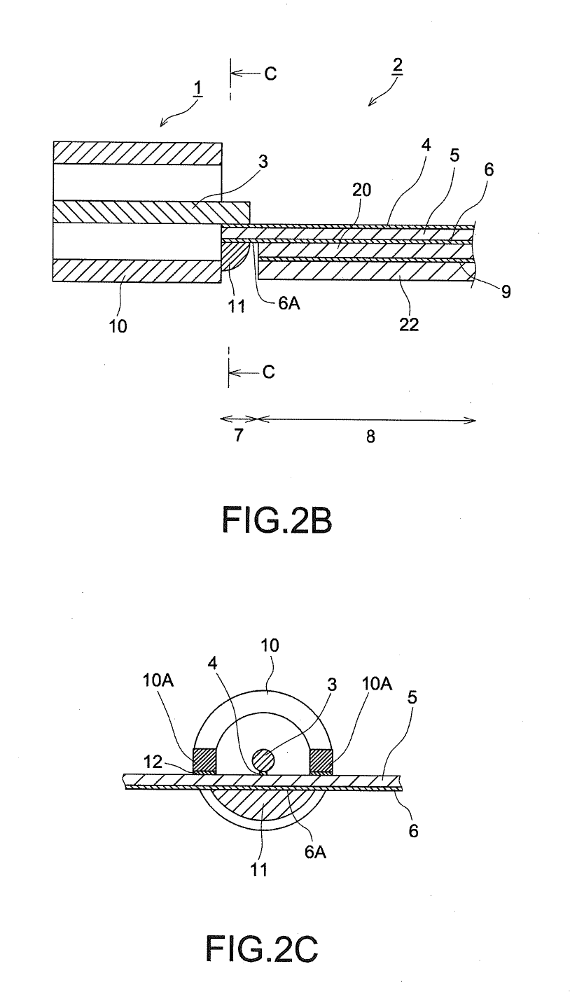

A multilayer wiring board according to embodiments of the present invention will be described below with reference to FIGS. 2A to 6B. Like or corresponding parts are denoted by like or corresponding reference numerals throughout drawings, and will not be described below repetitively.

FIGS. 2A to 2C are diagrams schematically showing a configuration of a multilayer wiring board 2 according to a first embodiment of the present invention. A small-sized connector 1, which corresponds to a coaxial structure according to the present invention, is mounted on the multilayer wiring board 2. FIG. 2A is a plan view of the multilayer wiring board 2, FIG. 2B is a cross-sectional view taken along line B-B of FIG. 2A, and FIG. 2C is a cross-sectional view taken along line C-C of FIG. 2B. Specifically, the multilayer wiring board 2 has a multilayered structure including a first dielectric layer 5 having a high-frequency signal line 4 formed on an upper surface thereof, a ground layer 6 formed on a lower surface of the first dielectric layer 5, a second dielectric layer 20 covering part of the ground layer 6, and at least one control signal layer 9 for forming a control signal circuit, and a third dielectric layer 22. At least one small-sized connector 1 is mounted onto the multilayer wiring board 2.

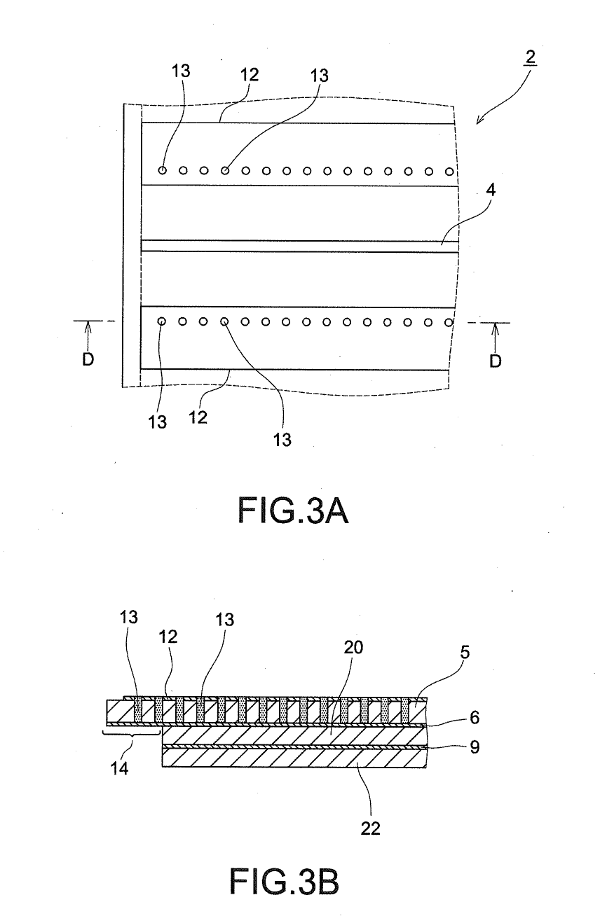

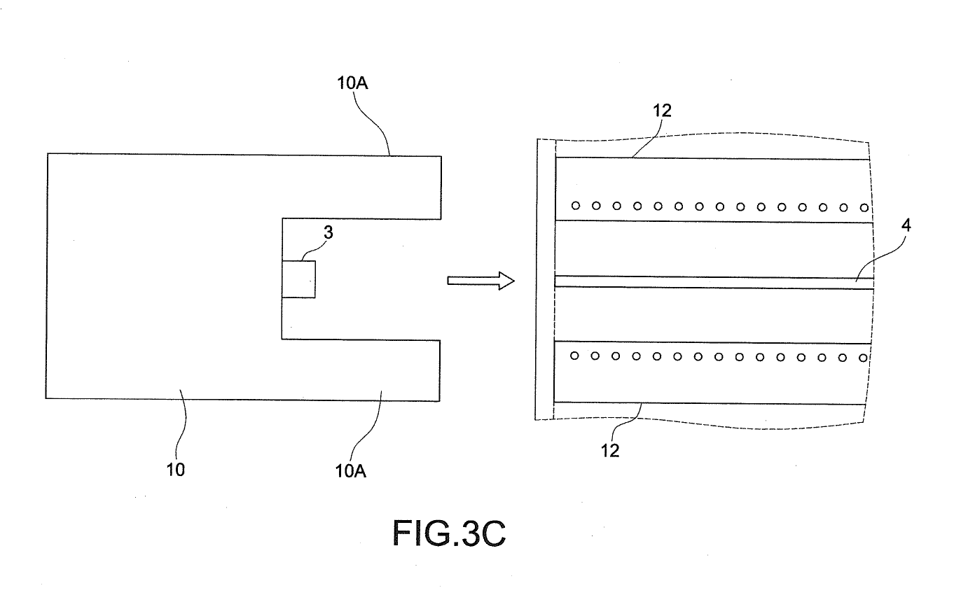

In this case, the line formation of the high-frequency signal line 4 is of a grounded coplanar type, which has ground electrode portions 12 formed on both sides of the central signal line 4 as shown in FIG. 3A. Each of the ground electrode portions 12 has a plurality of through holes 13 formed therein. The small-sized connector 1 has a center conductor 3 and a cylindrical outer conductor 10 with two projecting portions 10A (see FIG. 2A). The through holes 13 are used to electrically connect the projecting portions 10A of the outer conductor 10 of the small-sized connector 1 to the ground layer 6. From a state shown in FIG. 3C where the small-sized connector 1 has not been mounted on the multilayer wiring board 2, the small-sized connector 1 is mounted onto the multilayer wiring board 2 as shown in FIG. 2A. Upon mounting the small-sized connector 1 on the multilayer wiring board 2, the center conductor 3 of the small-sized connector 1 is brought into electrical contact with the high-frequency signal line 4 of the multilayer wiring board 2 at the shortest distance (for example, by joint, bonding, or adhesion). For example, the center conductor 3 of the small-sized connector 1 may be joined to the high-frequency signal line 4 of the multilayer wiring board 2 by a solder material, silver paste, or the like, or may be bonded to the high-frequency signal line 4 of the multilayer wiring board 2 by a conductive adhesive material.

The high-frequency signal line 4 is formed on the upper surface (first surface) of the dielectric layer 5, and the ground layer 6 is formed on the lower surface (second surface) of the dielectric layer 5. The width of the high-frequency signal line 4 and the thickness of the dielectric layer 5 are determined such that the characteristic impedance of the high-frequency signals is made equal to a predetermined value by the high-frequency signal line 4 and the ground layer 6.

According to the present embodiment, the ground layer 6 is exposed so as to form a ground exposure portion 6A at a connection portion 7 of the multilayer wiring board 2 at which the small-sized connector 1 is mounted on the multilayer wiring board 2. The control signal layer 9 in which a control signal circuit is provided is formed in an area 8 other than the connection portion 7 of the multilayer wiring board 2. More specifically, as shown in FIG. 2B, the second dielectric layer 20 is spaced from an edge of the first dielectric layer 5, so that a portion of the ground layer 6 is exposed on the edge of the first dielectric layer 5 (connection portion 7) to thus form a ground exposure portion 6A. A connection structure 11 is provided in the connection portion 7 for electrically connecting the ground exposure portion 6A of the ground layer 6 to the outer conductor 10 of the small-sized connector 1. For example, the connection structure 11 may be formed of a solder material, silver paste, or a conductive adhesive material applied to the ground exposure portion 6A.

With the above configuration of the multilayer wiring board 2, the outer conductor 10 and the ground layer 6 are connected directly to each other and are thus brought into satisfactory conduction with each other. Therefore, a high-frequency signal line for the ground can be formed by the shortest distance of connection. Thus, the ground inductance of the small-sized connector 1 and the multilayer wiring board 2 is prevented from increasing, thereby ensuring the waveform quality of high-speed data signals.

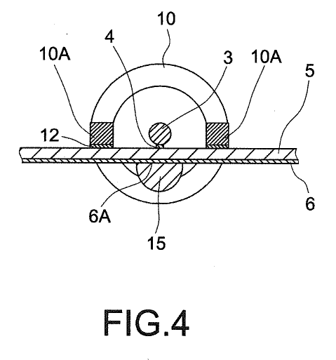

FIG. 4 is a diagram schematically showing a configuration of a multilayer wiring board with a small-sized connector according to a second embodiment of the present invention. FIG. 4 corresponds to FIG. 2C. As with the first embodiment, a portion of the ground layer 6 is exposed at the connection portion 7 at which the small-sized connector 1 is mounted on the multilayer wiring board 2, and the control signal layer 9 in which a control signal circuit is provided is formed in an area 8 other than the connection portion 7 of the multilayer wiring board 2 (see FIG. 2B).

In the second embodiment, only a portion of the ground exposure portion 6A of the ground layer 6 that is located near a portion opposed to the center conductor 3 of the small-sized connector 1 is electrically connected to the outer conductor 10 of the small-sized connector 1 in order to prevent the ground inductance from increasing at the connection portion 7 when the outer conductor 10 of the small-sized connector 1 and the ground exposure portion 6A of the ground layer 6 are brought into conduction with each other. In the second embodiment, a joining member 15 such as a solder material or silver paste is filled between the ground exposure portion 6A of the ground layer 6 and the outer conductor 10 of the small-sized connector 1 such that a portion of the ground exposure portion 6A of the ground layer 6 that is located near a portion opposed to the center conductor 3, for example, a portion 14 of the ground exposure portion 6A located right below the center conductor 3 (see FIG. 3B) is brought into conduction with the outer conductor 10 of the small-sized connector 1. Thus, the ground exposure portion 6A of the ground layer 6 and the outer conductor 10 of the small-sized connector 1 are electrically connected to each other.

The density of electric lines of force between the center conductor 3 of the small-sized connector 1 and the ground surface is the highest near the portion opposed to the center conductor 3. For example, the density of electric lines of force is the highest at the portion 14 located right below the center conductor 3, i.e., a portion located at the shortest distance from the ground surface. Under those circumstances, in the present embodiment, the ground exposure portion 6A of the ground layer 6 is connected to the outer conductor 10 with the shortest distance by the joining member 15 on the portion 14 located right below the center conductor 3. Therefore, disturbance of the electric lines of force between the high-frequency signal line 4 and the ground layer 6 are minimized at the connection portion 7 (see FIG. 2B) between the small-sized connector 1 and the multilayer wiring board 2. As a result, the ground inductance is prevented from increasing at the connection portion 7. Thus, satisfactory high-frequency transmission characteristics can be achieved.

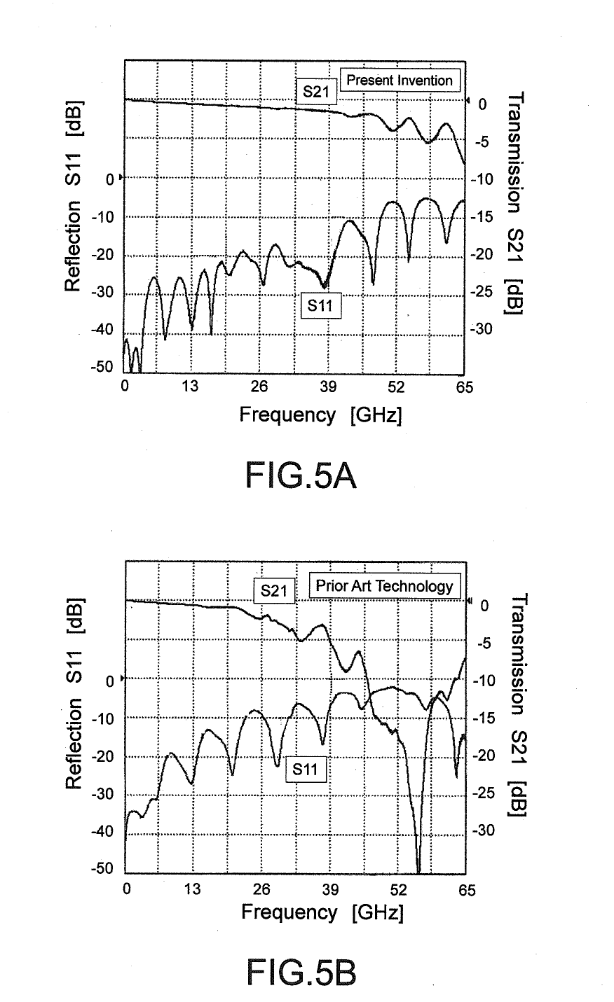

FIGS. 5A and 5B show measurement results of frequency characteristics of transmission and reflection of high-frequency signals in an example using a multilayer wiring board with a small-sized connector according to the present invention and a comparative example using a conventional multilayer wiring board with a small-sized connector. In those examples, through lines were formed with a length of 10 mm. FIG. 5A shows the results for the multilayer wiring board according to the present invention, and FIG. 5B shows the results for the conventional multilayer wiring board. Comparison of those results reveals that the through line according to the present invention exhibited less reflection and demonstrated more flatness of the transmission-frequency characteristic.

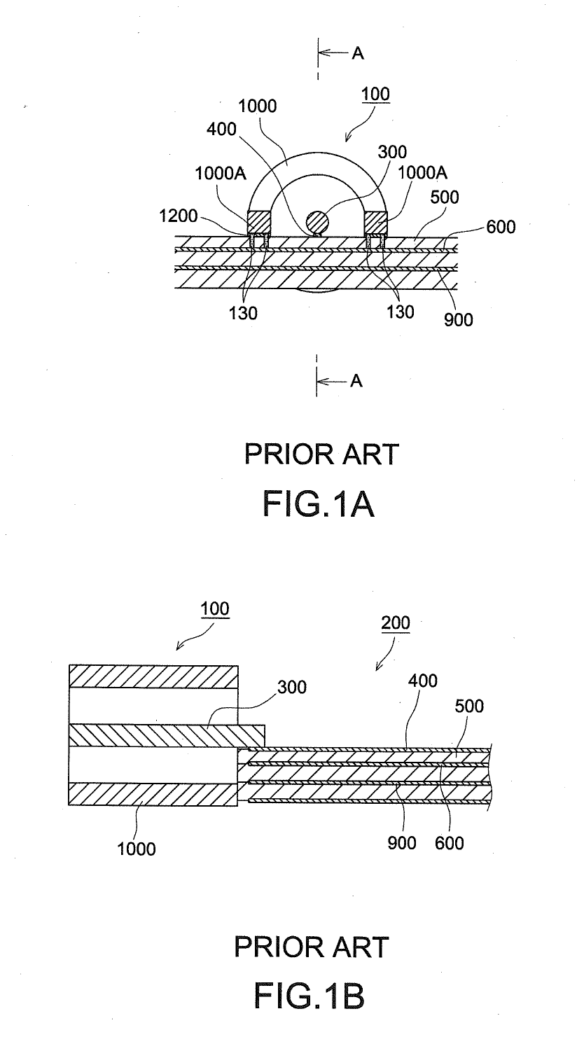

According to the present embodiment, the ground exposure portion 6A of the ground layer 6 is electrically connected to the outer conductor 10 at the shortest distance by the joining member 15 on the portion 14 located right below the center conductor 3. Accordingly, the discontinuity of the characteristic impedance is mitigated as compared to the conventional technology as shown in FIGS. 1A and 1B. Therefore, according to the present embodiment, the discontinuity of the characteristic impedance can be reduced so as to prevent quality degradation of waveforms of high-speed data signals.

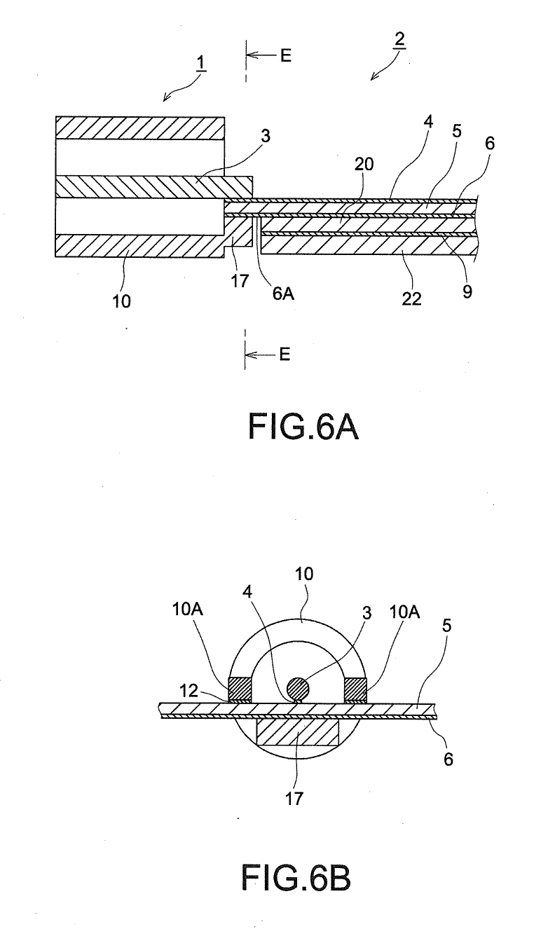

FIGS. 6A and 6B are diagrams schematically showing a configuration of a multilayer wiring board with a small-sized connector according to a third embodiment of the present invention. In the second embodiment illustrated in FIG. 4, the joining member 15 is filled between the portion 14 located right below the center conductor 3 and the outer conductor 10 of the small-sized connector 1. Nevertheless, as shown in FIGS. 6A and 6B, the shape of the small-sized connector 1 may be changed so as to have a contact protrusion 17 extending from the outer conductor 10 of the small-sized connector 1. This contact protrusion 17 may be adhered to and brought into direct contact with the ground exposure portion 6A of the ground layer 6 right below the center conductor 3.

The line formation of the high-frequency signal line 4 may not be of a grounded coplanar type and may be of a microstrip type, which has no ground patterns on the top side of a multilayer wiring board. The present invention is applicable to such a line formation, and the same advantageous effects can also be obtained in such a case.

The above embodiments illustrate examples in which the outer conductor 10 of the small-sized connector 1 is connected to the ground layer 6 via the through holes 13. Nevertheless, no through holes 13 may be formed in the multilayer wiring board 2 as long as the outer 10 of the small-sized connector 1 is electrically connected directly to the ground exposure portion 6A of the ground layer 6.

While a multilayer wiring board with a small-sized connector has been described in the above embodiments of the present invention, the present invention is not limited to the aforementioned embodiments. It should be understood that those skilled in the art would make any modifications to the above embodiments within the scope of the present invention. For example, instead of a small-sized connector, a high-frequency coaxial cable may be used as a coaxial structure to be mounted on and connected to a multilayer wiring board. The present invention is also effective in such a case. Specifically, when an outer conductor of a high-frequency coaxial cable is connected to a ground layer of a multilayer wiring board, the outer conductor of the high-frequency coaxial cable is connected directly to a ground exposure portion of the ground layer formed in the multilayer wiring board. With such an arrangement, the ground inductance is prevented from increasing, so that influence on the waveform quality of high-frequency data signals can be reduced.

As described above, according to the present invention, the ground layer of the multilayer wiring board is connected directly to the outer conductor of the coaxial structure. Therefore, the ground inductance is prevented from increasing, so that high-frequency connection having flat transmission-frequency characteristics and less reflection can be achieved between the coaxial structure and the multilayer wiring board. Accordingly, quality degradation of waveforms of high-speed data signals is suppressed. Thus, the present invention is advantageous to a multilayer wiring board on which a small-sized connector is to be mounted. For example, the present invention is advantageous to a multilayer wiring board with a small-sized connector that has increasingly been desired to be reduced in size.

Although certain preferred embodiments of the present invention have been shown and described in detail, it should be understood that various changes and modifications may be made therein without departing from the scope of the appended claims.

What is claimed is:

1. A multilayer wiring board to which a coaxial structure for transmitting an electric signal with a center conductor and an outer conductor is connected, the multilayer wiring board comprising:
a first dielectric layer;
a high-frequency signal line formed on a first surface of the first dielectric layer, the high-frequency signal line being electrically connectable to the center conductor of the coaxial structure;
a ground layer formed on a second surface of the first dielectric layer; and
a second dielectric layer covering part of the ground layer, the second dielectric layer being spaced from an edge of the first dielectric layer to which the coaxial structure is to be connected, thereby exposing a ground exposure portion of the ground layer on the edge of the first dielectric layer,
the ground layer being electrically connectable directly to the outer conductor of the coaxial structure at the ground exposure portion.

2. The multilayer wiring board as recited in claim 1, wherein the ground exposure portion of the ground layer is electrically connected directly to the outer conductor of the coaxial structure by at least one of a solder material, silver paste, and a conductive adhesive material applied to the ground exposure portion.

3. The multilayer wiring board as recited in claim 1, wherein the ground exposure portion of the ground layer is electrically connected directly to the outer conductor of the coaxial structure by a contact protrusion extending from the outer conductor of the coaxial structure.

4. The multilayer wiring board as recited in claim 1, wherein the ground exposure portion is located right below the center conductor of the coaxial structure when the coaxial structure is connected to the multilayer wiring board.

5. The multilayer wiring board as recited in claim 1, further comprising a control signal layer formed on a surface of the second dielectric layer for forming a control signal circuit.

6. The multilayer wiring board as recited in claim 1, wherein the coaxial structure comprises a connector to be mounted on the multilayer wiring board.
